(19) United States
(12) Patent Application Publication
(10) Pub. No.: US 2020/0411559 A1
(43) Pub. Date: Dec. 31, 2020

(54) ARRAY SUBSTRATE, DISPLAY PANEL AND DISPLAY DEVICE

(71) Applicant: Shanghai Tianma Micro-Electronics Co., Ltd., Shanghai (CN)

(72) Inventor: Tianyi Wu, Shanghai (CN)

(73) Assignee: Shanghai Tianma Micro-Electronics Co., Ltd., Shanghai (CN)

(21) Appl. No.: 16/735,264

(22) Filed: Jan. 6, 2020

(30) Foreign Application Priority Data
Jun. 26, 2019 (CN) 201910561991.3

(51) Int. Cl. H01L 27/12

(52) U.S. Cl. CPC H01L 27/124; H01L 27/3262; H01L 27/1225

(57) ABSTRACT

An array substrate includes a substrate, a first thin film transistor and a second thin film transistor, where the first thin film transistor includes a first active layer, a first A electrode and a first B electrode, where the first active layer includes an oxide semiconductor active layer; the second thin film transistor includes a second active layer, a second A electrode and a second B electrode, where the second active layer includes a low temperature polysilicon active layer; where the first active layer is disposed on a side of the second active layer facing away from the substrate, and in a direction perpendicular to a plane where the substrate is located, the first A electrode, the first B electrode, the second A electrode, the second B electrode are disposed between a film where the first active layer is located and a film where the second active layer is located.

### CROSS-REFERENCES TO RELATED APPLICATIONS

This application claims priority to a Chinese patent application No. 201910561991. 3 filed on Jun. 26, 2019, the disclosure of which is incorporated herein by reference in its entirety.

### TECHNICAL FIELD

The present disclosure relates to the field of display technologies and, in particular, to an array substrate, a display panel and a display device.

### BACKGROUND

A Low Temperature Polycrystalline Oxide (LTPO) technology is a technology for preparing a low temperature polysilicon thin film transistor and an oxide semiconductor thin film transistor on the same backplate. The low temperature polysilicon thin film transistor has advantages of a high switching speed and small power consumption. The oxide semiconductor thin film transistor has advantages of high carrier mobility, low deposition temperature and high transparency. The LTPO technology can fully take advantages of the low temperature polysilicon thin film transistor and the oxide semiconductor thin film transistor, ensuring good display performance of the display device.

However, optimal performance of the LTPO technology is difficult to achieve since the current preparation process may damage an oxide semiconductor active layer of the oxide semiconductor thin film transistor.

### SUMMARY

In view of this, the present disclosure provides an array substrate, a display panel and a display device to solve the problem in the related art that an oxide semiconductor active layer of an oxide semiconductor thin film transistor is damaged in a preparation process for a low temperature polysilicon thin film transistor and the oxide semiconductor thin film transistor.

In a first aspect, an embodiment of the present disclosure provides an array substrate. The array substrate includes a substrate, a first thin film transistor and a second thin film transistor.

The first thin film transistor and the second thin film transistor are disposed on a side of the substrate. The first thin film transistor includes a first active layer, a first A electrode and a first B electrode, where the first active layer includes an oxide semiconductor active layer. The second thin film transistor includes a second active layer, a second A electrode and a second B electrode, where the second active layer includes a low temperature polysilicon active layer.

A film where the first active layer is located is disposed on a side of a film where the second active layer is located facing away from the substrate. In a direction perpendicular to a plane where the substrate is located, a film where the first A electrode is located, a film where the first B electrode is located, a film where the second A electrode is located and a film where the second B electrode is located each are disposed between the film where the first active layer is located and the film layer where the second active layer is located.

In a second aspect, an embodiment of the present disclosure further provides a display panel including the array substrate described in the first aspect.

In a third aspect, an embodiment of the present disclosure further provides a display device including the display panel described in the second aspect.

The array substrate, the display panel and the display device are provided in the embodiments of the present disclosure. The first active layer is disposed on the side of the second active layer facing away from the substrate, and in the direction perpendicular to the plane where the substrate is located, the film where the first A electrode is located, the film where the first B electrode is located, the film where the second A electrode is located and the film where the second B electrode is located each are disposed between the film where the first active layer is located and the film where the second active layer is located, so that a damage to the first active layer, that is, the oxide semiconductor active layer, can be avoided, advantages of the oxide semiconductor thin film transistor and the low temperature polysilicon thin film transistor can be fully taken, and display performance can be improved.

### BRIEF DESCRIPTION OF DRAWINGS

Other features, objects and advantages of the present disclosure will become more apparent from a detailed description of non-restrictive embodiments with reference to the drawings.

FIG. 1 is a structural diagram of a circuit of an LTPO technology;

FIG. 2 is a structural diagram of an array substrate in the related art;

FIG. 3 is a sectional view taken along a line A-A′ of the array substrate shown in FIG. 2;

FIG. 4 is a structural diagram of an array substrate according to an embodiment of the present disclosure;

FIG. 5 is a sectional view taken along a line B-B′ of the array substrate shown in FIG. 4;

FIG. 6 is a structural diagram of another array substrate according to an embodiment of the present disclosure;

FIG. 7 is a sectional view taken along a line C-C′ of the array substrate shown in FIG. 6;

FIG. 8 is a structural diagram of another array substrate according to an embodiment of the present disclosure;

FIG. 9 is a sectional view taken along a line D-D′ of the array substrate shown in FIG. 8;

FIG. 10 is a structural diagram of another array substrate according to an embodiment of the present disclosure;

FIG. 11 is a sectional view taken along a line E-E′ of the array substrate shown in FIG. 10;

FIG. 12 is another sectional view taken along a line B-B′ of the array substrate shown in FIG. 4;

FIG. 13 is a sectional view of a display panel according to an embodiment of the present disclosure; and

FIG. 14 is a structural diagram of a display device according to an embodiment of the present disclosure.

### DETAILED DESCRIPTION

In order to make the objects, technical solutions and advantages of the present disclosure clearer, the technical solutions of the present disclosure will be described below in detail in conjunction with the drawings in the embodiments of the present disclosure and the specific embodiments. Apparently, the described embodiments are part, not all, of the embodiments of the present disclosure, and based on the embodiments of the present disclosure, other embodiments obtained by those skilled in the art on the premise that no creative work is done are within the scope of the present disclosure.

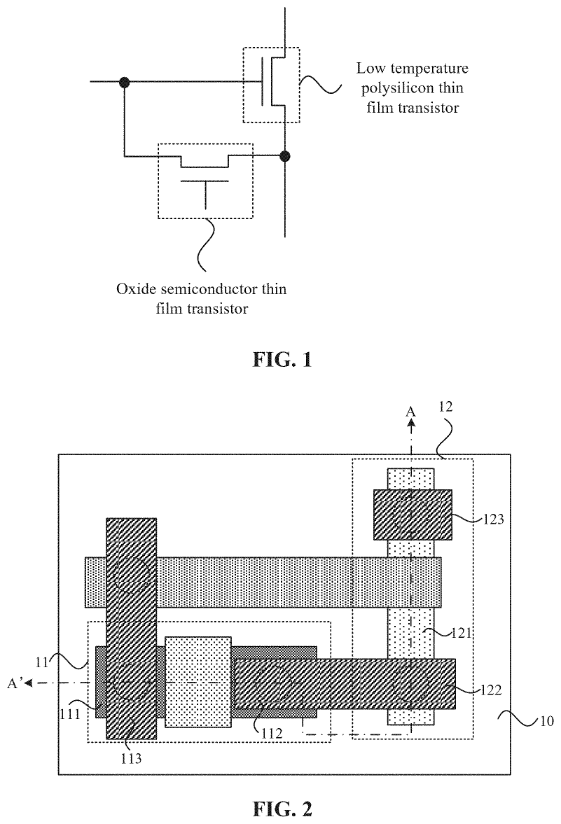

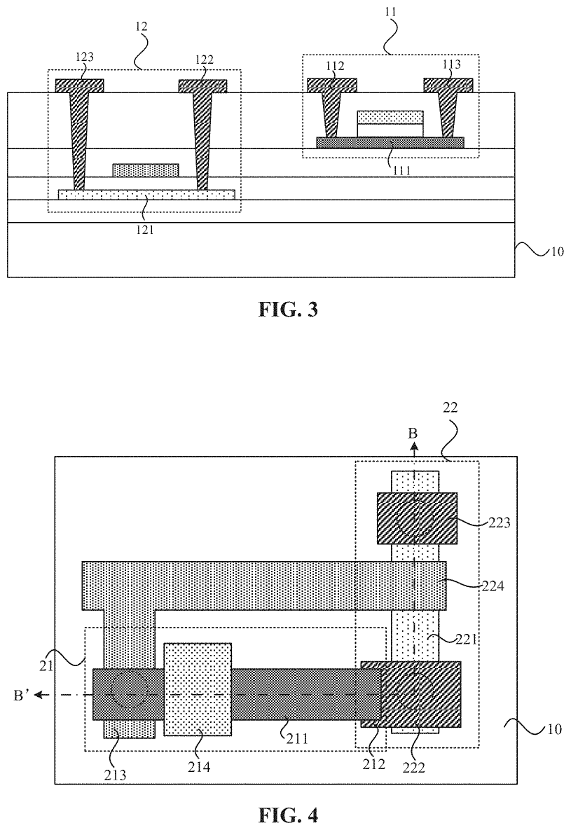

FIG. 1 is a structural diagram of a circuit of an LTPO technology. FIG. 2 is a structural diagram of an array substrate in the related art. FIG. 3 is a sectional view taken along a line A-A′ of the array substrate shown in FIG. 2. As shown in FIG. 2 and FIG. 3, the array substrate in the related art includes a substrate 10, an oxide semiconductor thin film transistor 11 and a low temperature polysilicon thin film transistor 12, where the oxide semiconductor thin film transistor 11 and the low temperature polysilicon thin film transistor 12 are disposed on a side of the substrate 10; the oxide semiconductor thin film transistor 11 includes an oxide semiconductor active layer 111, a first source 112 and a first drain 113; and the low temperature polysilicon thin film transistor 12 includes a low temperature polysilicon active layer 121, a second source 122 and a second drain 123. The oxide semiconductor active layer 111 is disposed on a side of the first source 112 and the first drain 113 facing towards the substrate 10. The low temperature polysilicon active layer 121 is disposed on a side of the second source 122 and the second drain 123 facing towards the substrate 10. The first source 112, the first drain 113, the second source 122 and the second drain 123 are arranged at a same layer. The low temperature polysilicon active layer 121 needs to be cleaned by using hydrofluoric acids when the second source 122 and the second drain 123 are prepared, to prevent impurities on a surface of the low temperature polysilicon active layer 121 from affecting a contact effect of the second source 122 and the second drain 123 with the low temperature polysilicon active layer 121. However, the first source 112, the first drain 113, the second source 122 and the second drain 123 are arranged at the same layer, and vias through which the first source 112, the first drain 113, the second source 122 and the second drain 123 are connected to the active layers are prepared in a prepare process; therefore the oxide semiconductor active layer 111 is damaged by the hydrofluoric acids when the low temperature polysilicon active layer 121 is cleaned by using the hydrofluoric acids, thereby affecting performance of the oxide semiconductor thin film transistor, and further affecting a display effect of the whole display device.

Based on the above technical problems, an embodiment of the present disclosure provides an array substrate. The array substrate includes a substrate, a first thin film transistor and a second thin film transistor. The first thin film transistor and the second thin film transistor are located on a side of the substrate. The first thin film transistor includes a first active layer, a first A electrode and a first B electrode. The first active layer includes an oxide semiconductor active layer. The second thin film transistor includes a second active layer, a second A electrode and a second B electrode. The second active layer includes a low temperature polysilicon active layer. A film where the first active layer is located is disposed on a side of a film where the second active layer is located facing away from the substrate. In a direction perpendicular to a plane where the substrate is located, a film where the first A electrode is located, a film where the first B electrode is located, a film where the second A electrode is located and a film where the second B electrode is located each are disposed between the film where the first active layer is located and the film where the second active layer is located. With the above technical solutions, the film where the first A electrode is located, the film where the first B electrode is located, the film where the second A electrode is located and the film where the second B electrode is located each are disposed between the film where the first active layer is located and the film where the second active layer is located, so that a damage of the hydrofluoric acids to the first active layer, that is, the oxide semiconductor active layer, can be avoided when the low temperature polysilicon active layer is cleaned by using the hydrofluoric acids, thereby taking full advantages of the oxide semiconductor thin film transistor and the low temperature polysilicon thin film transistor, and improving display performance.

The above is the core idea of the present disclosure, and technical solutions in the embodiments of the present disclosure will be described clearly and completely in conjunction with the drawings in the embodiments of the present disclosure. Based on the embodiments of the present disclosure, all other embodiments obtained by those skilled in the art without creative work are within the scope of the embodiments of the present disclosure.

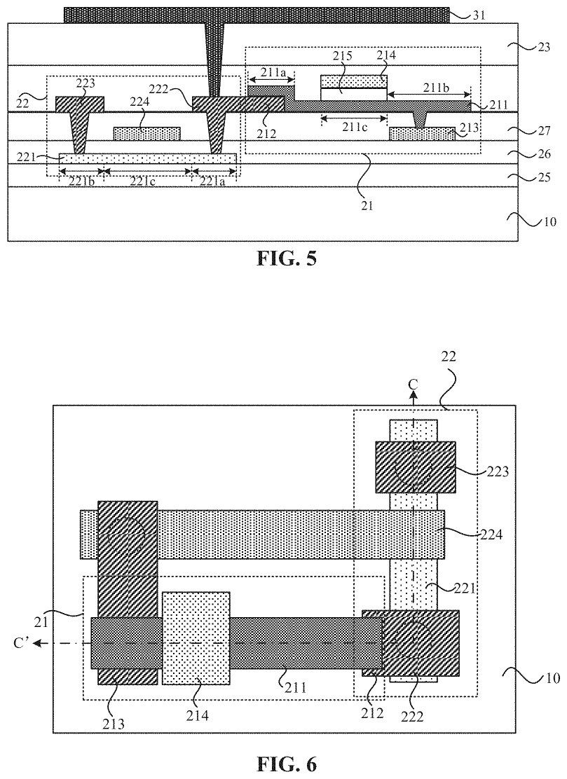

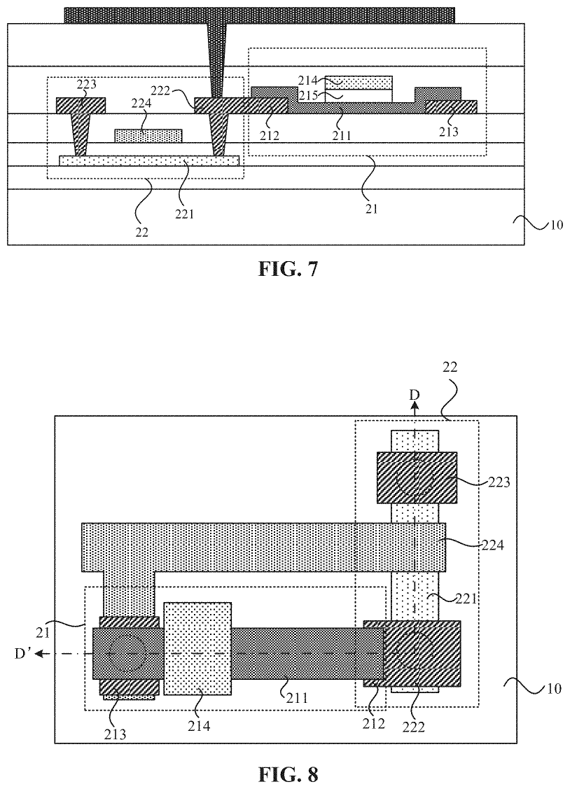

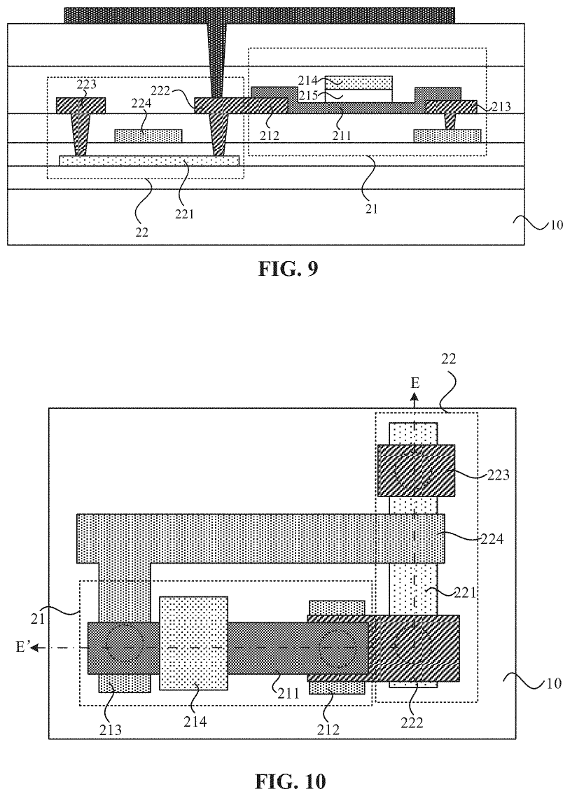

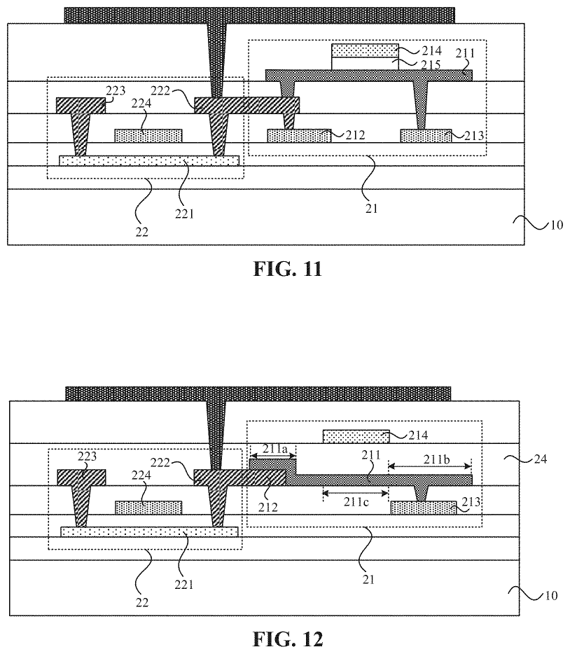

FIG. 4 is a structural diagram of an array substrate according to an embodiment of the present disclosure. FIG. 5 is a sectional view taken along a line B-B′ of the array substrate shown in FIG. 4. FIG. 6 is a structural diagram of another array substrate according to an embodiment of the present disclosure. FIG. 7 is a sectional view taken along a line C-C′ of the array substrate shown in FIG. 6. FIG. 8 is a structural diagram of another array substrate according to an embodiment of the present disclosure. FIG. 9 is a sectional view taken along a line D-D′ of the array substrate shown in FIG. 8. FIG. 10 is a structural view diagram of another array substrate according to an embodiment of the present disclosure. FIG. 11 is a sectional view taken along a line E-E′ of the array substrate shown in FIG. 10. As shown in FIG. 4 to FIG. 11, the array substrate in the embodiments of the present disclosure includes the substrate 10, the first thin film transistor 21 and the second thin film transistor 22.

The first thin film transistor 21 and the second thin film transistor 22 are disposed on the side of the substrate 10. The first thin film transistor 21 includes the first active layer 211, the first A electrode 212 and the first B electrode 213. The first active layer 211 includes the oxide semiconductor active layer. The second thin film transistor 22 includes the second active layer 221, the second A electrode 222 and the second B electrode 223. The second active layer 221 includes the low temperature polysilicon active layer.

The film where the first active layer 211 is located is disposed on the side of the film where the second active layer 221 is located facing away from the substrate 10. In the direction perpendicular to the plane where the substrate 10 is located, the film where the first A electrode 212 is located, the film where the first B electrode 213 is located, the film where the second A electrode 222 is located and the film where the second B electrode 223 is located each are disposed between the film where the first active layer 211 is located and the film where the second active layer 221 is located.

As shown in FIG. 4 to FIG. 9, the first thin film transistor 21 and the second thin film transistor 22 are disposed on the substrate 10, the first thin film transistor 21 includes the oxide semiconductor active layer, and the second thin film transistor 22 includes the low temperature polysilicon active layer, which ensures that the advantages of the first thin film transistor 21 and the second thin film transistor 22 are fully taken and the display device has good display performance. Furthermore, the film where the first active layer 211 is located is disposed on the side of the film where the second active layer 221 is located facing away from the substrate 10, and in the direction perpendicular to the plane where the substrate 10 is located, the film where the first A electrode 212 is located, the film where the first B electrode 213 is located, the film where the second A electrode 222 is located and the film where the second B electrode 223 is located each are disposed between the film where the first active layer 211 is located and the film where the second active layer 221 is located. In this way, when the second A electrode 222 and the second B electrode 223 are prepared, the damage of the hydrofluoric acids to the first active layer 211 can be avoided when the second active layer 221 is cleaned by using the hydrofluoric acids, thereby taking full advantages of the first thin film transistor 21 of high carrier mobility, low deposition temperature and high transparency, and significantly improving a display effect of the display device.

Optionally, the substrate 10 provided in the embodiments of the present disclosure may be a flexible substrate or a rigid substrate, which is not limited in the embodiments of the present disclosure.

It is to be noted that the embodiments of the present disclosure do not define whether the first thin film transistor 21 or the second thin film transistor 22 is a P-type thin film transistor or an N-type thin film transistor. Specifically, when the first thin film transistor 21 is the N-type thin film transistor, the first A electrode 212 is a source of the first thin film transistor 21, and the first B electrode 213 is a drain of the first thin film transistor 21. When the first thin film transistor 21 is the P-type thin film transistor, the first A electrode 212 is the drain of the first thin film transistor 21, and the first B electrode 213 is the source of the first thin film transistor 21. Similarly, when the second thin film transistor 22 is the N-type thin film transistor, the second A electrode 222 is a source of the second thin film transistor 22, and the second B electrode 223 is a drain of the second thin film transistor 22. When the second thin film transistor 22 is the P-type thin film transistor, the second A electrode 222 is the drain of the second thin film transistor 22, and the second B electrode 223 is the source of the second thin film transistor 21.

Optionally, with continued reference to FIG. 2 and FIG. 3, the array substrate in the related art has a risk of damaging the oxide semiconductor active layer; in addition, the first source 112 and the first drain 113 each need to be connected to the oxide semiconductor active layer 111 through vias, the second source 122 and the second drain 123 each need to be connected to the low temperature polysilicon active layer 121 through vias, and a gate of the low temperature polysilicon thin film transistor 12 needs to be electrically connected to the source 112 or the drain 113 of the oxide semiconductor thin film transistor 11 through vias, and therefore, the array substrate in the related art needs to be punched multiple times. The array substrate in the related art needs to be punched five times at positions shown by dotted circles in FIG. 2. Due to a process limitation, the vias need to occupy a certain area, and more vias occupy a larger space, which is not conducive for the display device to achieve a higher pixel resolution. Meanwhile, a complex punching process will reduce preparation efficiency of the array substrate and increase preparation costs of the array substrate, which is not conducive to batch production. As for the array substrate in the embodiments of the present disclosure, in the direction perpendicular to the plane where the substrate 10 is located, the film where the first A electrode 212 is located, the film where the first B electrode 213 is located, the film where the second A electrode 222 is located and the film where the second B electrode 223 is located each are disposed between the film where the first active layer 211 is located and the film where the second active layer 221 is located, which has a potential technical effect of reducing the number of punched vias (for example, the first active layer 211 is electrically connected to the first A electrode 212 and/or the first B electrode 213 through direct contact), and can reduce the space occupied by the vias, improve the pixel resolution of the display device and the preparation efficiency of the array substrate, and reduce the preparation costs of the array substrate.

How to reduce the number of punched vias is described in detail below.

Optionally, with continued reference to FIG. 4 and FIG. 5, the first A electrode 212 and the second A electrode 222 are arranged at a same layer and are electrically connected to each other, and in the direction perpendicular to the plane where the substrate 10 is located, the first active layer 211 has an overlapping portion with the first B electrode 212, where for the overlapping portion, a surface of the first active layer 211 facing towards the substrate 10 is in direct contact with a surface of the first A electrode 212 facing away from the substrate 10.

Exemplarily, as shown in FIG. 4 and FIG. 5, in the direction perpendicular to the plane where the substrate 10 is located, the first active layer 211 has the overlapping portion with the first B electrode 212, where for the overlapping portion, the surface of the first active layer 211 facing towards the substrate 10 is in direct contact with the surface of the first A electrode 212 facing away from the substrate 10. A manner that the first active layer 211 and the first A electrode 212 are electrically connected through the direct contact replaces a manner that the first active layer 211 and the first electrode 212 are electrically connected through the punched vias, thereby reducing the number of punched vias and the space occupied by the punched vias, improving the pixel resolution of the display device and the preparation efficiency of the array substrate, and reducing the preparation costs of the array substrate.

Optionally, with continued reference to FIG. 4 and FIG. 5, the second thin film transistor 22 further includes a second gate 224, where a film where the second gate 224 is located is disposed between the film where the second active layer 221 is located and the film where the second A electrode 222 and the second B electrode 223 are located, and the first B electrode 213 and the second gate 224 are arranged at a same layer and are electrically connected to each other; and the first B electrode 213 is electrically connected to the first active layer 211 through a first via.

Exemplarily, a manner that the first B electrode 213 and the second gate 224 are arranged at the same layer and are electrically connected replaces a manner that the first B electrode 213 and the second gate 224 are electrically connected through a punched via, thereby reducing the number of punched vias and the space occupied by the punched vias, improving the pixel resolution of the display device and the preparation efficiency of the array substrate, and reducing the preparation costs of the array substrate.

In conclusion, in conjunction with FIG. 4 and FIG. 5, the surface of the first active layer 211 facing towards the substrate 10 is in direct contact with the surface of the first A electrode 212 facing away from the substrate 10, and the first B electrode 213 and the second gate 224 are arranged at the same layer and are electrically connected, so that an electrical connection between the first thin film transistor 21 and the second thin film transistor 22 can be achieved, the advantages of the first thin film transistor 21 and the second thin film transistor 22 can be fully taken, and the good display performance of the display device can be ensured. Meanwhile, the first active layer 211 can be prevented from being electrically connected to the first A electrode 212 through the punched via, and the first B electrode 213 can be prevented from being electrically connected to the second gate 224 through the punched via, thereby reducing two punching processes, improving the pixel resolution of the display device by providing pixels in the space occupied by the punched vias and the preparation efficiency of the array substrate, and reducing the preparation costs of the array substrate.

Optionally, with continued reference to FIG. 6 to FIG. 9, in the direction perpendicular to the plane where the substrate 10 is located, the first active layer 211 has the overlapping portion with the first A electrode 212, where for the overlapping portion, the surface of the first active layer 211 facing towards the substrate 10 is in direct contact with the surface of the first A electrode 212 facing away from the substrate 10; the first A electrode 212 and the first B electrode 213 are arranged at a same layer; and in the direction perpendicular to the plane where the substrate 10 is located, the first active layer 211 has an overlapping portion with the first B electrode 213, where for the overlapping portion, the surface of the first active layer 211 facing towards the substrate 10 is in direct contact with a surface of the first B electrode 213 facing away from the substrate 10. Furthermore, the second thin film transistor 22 further includes the second gate 224, where the film where the second gate 224 is located is disposed between the film where the second active layer 221 is located and the film where the second A electrode 222 and the second B electrode 223 are located, and the first B electrode 213 is electrically connected to the second gate 224 through a second via.

Exemplarily, as shown in FIG. 6 to FIG. 9, in the direction perpendicular to the plane where the substrate 10 is located, the first active layer 211 has the overlapping portion with each of the first A electrode 212 and the first B electrode 213, and the surface of the first active layer 211 facing towards the substrate 10 is in direct contact with the surface of the first A electrode 212 facing away from the substrate 10 and the surface of the first B electrode 213 facing away from the substrate 10. A manner that the first active layer 211 is electrically connected to the first A electrode 212 and the first B electrode 213 through the direct contact replaces a manner that the first active layer 211 and the first A electrode 212 are electrically connected through the punched via and the first active layer 211 and the first B electrode 213 are electrically connected through the punched via, thereby reducing two punching processes, improving the pixel resolution of the display device by providing pixels in the space occupied by the punched vias and the preparation efficiency of the array substrate, and reducing the preparation costs of the array substrate. Furthermore, the first B electrode 213 is electrically connected to the second gate 224 through the second via, so that the electrical connection between the first thin film transistor 21 and the second thin film transistor 22 is achieved, the advantages of the first thin film transistor 21 and the second thin film transistor 22 can be fully taken, and the good display performance of the display device is ensured. It is to be noted that the first B electrode 213 and the second gate 224 are electrically connected through the second via, which may be implemented by extending the first B electrode 213 towards the second gate 224 to ensure that a vertical projection of the first B electrode 213 on the plane where the substrate 10 is located overlaps a vertical projection of the second gate 224 on the plane where the substrate 10 is located, as shown in FIG. 6 and FIG. 7, or which may also be implemented by extending the second gate 224 towards the first B electrode 213 to ensure that the vertical projection of the first B electrode 213 on the plane where the substrate 10 is located overlaps the vertical projection of the second gate 224 on the plane where the substrate 10 is located, as shown in FIG. 8 and FIG. 9. The above two manners are not limited in the embodiments of present disclosure, and a specific implementation manner needs to be selected according to a practical process.

Optionally, with continued reference to FIG. 10 and FIG. 11, the second thin film transistor 22 further includes the second gate 224, where the film where the second gate 224 is located is disposed between the film where the second active layer 221 is located and the film where the second A electrode 222 and the second B electrode 223 are located, the first A electrode 212, the first B electrode 213 and the second gate 224 are arranged at a same layer, and the first B electrode 213 is electrically connected to the second gate 224; a vertical projection of the first active layer 211 on the substrate 10 overlaps a vertical projection of the second A electrode 222 on the substrate 10; the first A electrode 212 is electrically connected to the second A electrode 222 and the first active layer 211 separately through a third via; and the first B electrode 213 is electrically connected to the first active layer 211 through a fourth via.

Exemplarily, the first A electrode 212, the first B electrode 213 and the second gate 224 are arranged at the same layer, and the manner that the first B electrode 213 and the second gate 224 are arranged at the same layer and are electrically connected replaces the manner that the first B electrode 213 and the second gate 224 are electrically connected through the punching via, thereby reducing the number of punched vias and the space occupied by the punched vias, improving the pixel resolution of the display device and the preparation efficiency of the array substrate, and reducing the preparation costs of the array substrate. Meanwhile, the vertical projection of the first active layer 211 on the substrate 10 overlaps the vertical projection of the second A electrode 222 on the substrate 10, the first A electrode 212 is electrically connected to the second A electrode 222 and the first active layer 211 separately through the third via, and the first B electrode 213 is electrically connected to the first active layer 211 through the fourth via, so that the electrical connection between the first thin film transistor 21 and the second thin film transistor 22 can be achieved, the advantages of the first thin film transistor 21 and the second thin film transistor 22 can be fully taken, and the good display performance of the display device can be ensured.

It is to be noted that the first A electrode 212 is electrically connected to the second A electrode 222 and the first active layer 211 separately through the third via, which may be that the first A electrode 212 and the second A electrode 222 are electrically connected through a via between the first A electrode 212 and the second A electrode 222, and the second A electrode 222 and the first active layer 211 are electrically connected through a via between the second A electrode 222 and the first active layer 211, so that the first A electrode 212 and the first active layer 211 are electrically connected. The via between the first A electrode 212 and the second A electrode 222 and the via between the second A electrode 222 and the first active layer 211 coincide in the direction perpendicular to the plane where the substrate 10 is located, and therefore, that the first A electrode 212 is electrically connected to the second A electrode 222 and the first active layer 211 separately through the third via is described.

In conclusion, the film where the first active layer 211 is located is disposed on the side of the film where the second active layer 221 is located facing away from the substrate 10; in the direction perpendicular to the plane where the substrate 10 is located, the film where the first A electrode 212 is located, the film where the first B electrode 213 is located, the film where the second A electrode 222 is located and the film where the second B electrode 223 is located each are disposed between the film where the first active layer 211 is located and the film where the second active layer 221 is located; and at least one of the first A electrode 212 and the first B electrode 213 is directly electrically connected to the first active layer 211, or the first B electrode 213 and the second gate 224 are arranged at the same layer and are electrically connected to each other, which can prevent the first active layer 211 from being damaged, reduce the number of punched vias, improve the pixel resolution of the display device and the preparation efficiency of the array substrate, and reduce the preparation costs of the array substrate.

Optionally, with continued reference to FIG. 5, the first thin film transistor 21 further includes a first gate 214; the array gate further includes a first gate insulating layer 215 and a first passivation layer 23; and the first active layer 211 includes a first A electrode area 211a, a first B electrode area 211b and a first channel area 211c between the first A electrode area 211a and the first B electrode area 211b; where the first gate insulating layer 215 is disposed on a side of the first active layer 211 facing away from the substrate 10, and a vertical projection of the first gate insulating layer 215 on the substrate 10 overlaps a vertical projection of the first channel area 211c on the substrate 10; the first gate 214 is disposed on a side of the first gate insulating layer 215 facing away from the substrate 10, and a vertical projection of the first gate 214 on the substrate 10 overlaps the vertical projection of the first gate insulating layer 215 on the substrate 10; and the first passivation layer 23 covers the first gate 214, a part of the first active layer 211, the second A electrode 222 and the second B electrode 223.

Exemplarily, the first gate insulating layer 215 is disposed on the side of the first active layer 211 facing away from the substrate 10, and the vertical projection of the first gate insulating layer 215 on the substrate 10 overlaps the vertical projection of the first channel area 211c on the substrate 10. After the first gate insulating layer 215 is prepared as a whole layer, the first gate insulating layer 215 above the first A electrode area 211a and the first B electrode area 211b is etched away, a surface treatment process is then employed to process the first A electrode area 211a and the first B electrode area 211b, to ensure that a carrier concentration in the first A electrode area 211a and the first B electrode area 211b is larger than a carrier concentration in the first channel area 211c and the first thin film transistor 21 can operate normally. Furthermore, the surface treatment process is employed to process the first A electrode area 211a and the first B electrode area 211b, to ensure stable performance of the first A electrode area 211a and the first B electrode area 211 b and stable performance of the first thin film transistor 21.

FIG. 12 is another sectional view taken along a line B-B′ of the array substrate shown in FIG. 4. As shown in FIG. 12, the first thin film transistor 21 further includes the first gate 214; the array gate further includes a second passivation layer 24; and the first active layer 211 includes the first A electrode area 211a, the first B electrode area 211b and the first channel area 211c between the first A electrode area 211a and the first B electrode area 211b; where the second passivation layer 24 covers the first active layer 211, the second A electrode 222 and the second B electrode 223; the first gate 214 is disposed on a side of the second passivation layer 24 facing away from the substrate 10; and the vertical projection of the first gate 214 on the substrate 10 overlaps the vertical projection of the first channel area 211c on the substrate 10.

Exemplarily, after the second passivation layer 24 is prepared, ion implantation may be performed in areas corresponding to the first A electrode area 211a and the first B electrode area 211b to obtain the first A electrode area 211a and the first B electrode area 211b with a larger carrier concentration. The first A electrode area 211a and the first B electrode area 211b are obtained through the ion implantation, so that the first gate insulating layer can be prevented from being prepared and etched away, the array substrate has a simple preparation process and high preparation efficiency, and the array substrate has a small number of film layers which facilitates the thinning of the array substrate.

Optionally, with continued reference to FIG. 5, the array substrate in the embodiments of the present disclosure may further include a buffer layer 25, a second gate insulating layer 26 and an interlayer insulating layer 27, and the second thin film transistor 22 further includes the second gate 224, where the buffer layer 25 is disposed between the film where the second active layer 221 is located and the substrate 10; and the second active layer 221 includes a second A electrode area 221a, a second B electrode area 221b and a second channel area 221c between the second A electrode area 221a and the second B electrode area 221b; where the second gate insulating layer 26 is disposed on a side of the second active layer 221 facing away from the substrate 10; the second gate 224 is disposed on a side of the second gate insulating layer 26 facing away from the substrate 10, and a vertical projection of the second gate 224 on the substrate 10 overlaps a vertical projection of the second channel area 221c on the substrate 10; the interlayer insulating layer 27 is disposed on a side of the second gate 224 facing away from the substrate 10; and the second A electrode 222 and the second B electrode 223 are disposed on a side of the interlayer insulating layer 27 facing away from the substrate 10. The second A electrode 222 is electrically connected to the second A electrode area 221a through a fifth via which penetrates through the interlayer insulating layer 27 and the second gate insulating layer 26, and the second B electrode 223 is electrically connected to the second B electrode area 221b through a sixth via which penetrates through the interlayer insulating layer 27 and the second gate insulating layer 26.

Exemplarily, the buffer layer 25 is disposed between the substrate 10 and the second active layer 221, which can match the substrate 10 and the second active layer 221, eliminate the impact of impurities and particles which may exist inside or on a surface of the substrate 10 on the second active layer 221, and optimize a driving process of the second thin film transistor 22. The second gate insulating layer 26 and the interlayer insulating layer 27 may be made of an oxide of silicon or a nitride of silicon, which is not limited in the embodiments of the present disclosure.

Optionally, with continued reference to FIG. 5, the array substrate in the embodiments of the present disclosure may further include an anode electrode 31, where the anode electrode 31 is electrically connected to the second A electrode 222, and configured to receive a driving signal from the second first electrode 222 for display.

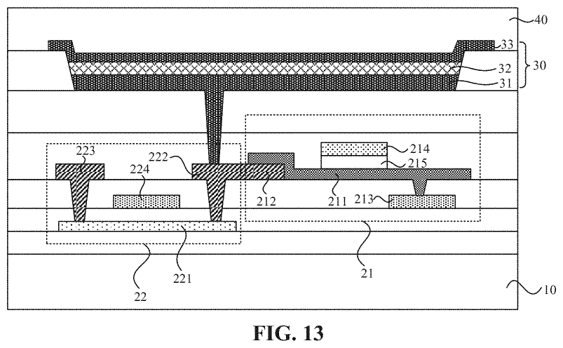

Based on the same inventive concept, an embodiment of the present disclosure further provides a display panel. FIG. 13 is a structural diagram of a display panel according to an embodiment of the present disclosure. As shown in FIG. 13, the display panel in the embodiments of the present disclosure includes the array substrate according to the embodiments of the present disclosure, and further includes an opposing substrate 40 and a light-emitting element 30 between the array substrate and the opposing substrate 40, where the light-emitting element 30 may include the anode electrode 31, a light-emitting material layer 32 and a cathode electrode 33, where the anode electrode 31, the light-emitting material layer 32 and the cathode electrode 33 are sequentially stacked. Optionally, the display panel in the embodiment of the present disclosure may further include an encapsulation layer (not shown in the figure). The encapsulation layer is disposed between the light-emitting element 30 and the opposing substrate 40 and configured to provide water and oxygen protection for the light-emitting element 30. Optionally, the encapsulation layer may be a glass encapsulation layer or a thin film encapsulation layer, which is not limited in the embodiment of the present disclosure.

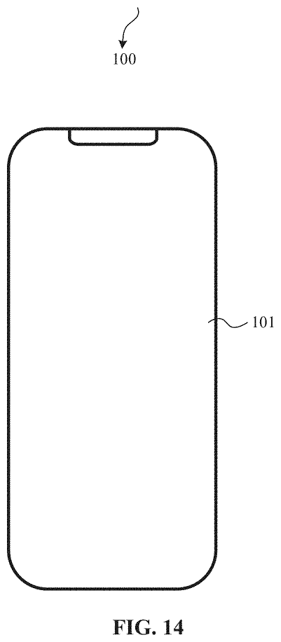

Based on the same inventive concept, an embodiment of the present disclosure further provides a display device. FIG. 14 is a schematic diagram of a display device according to an embodiment of the present disclosure. A display device 100 in the embodiment of the present disclosure includes the display panel 101 according to any embodiment of the present disclosure. Optionally, the display device in the embodiment of the present disclosure may be a mobile phone shown in FIG. 14, or may be a computer, a television, an smart wearable display device, or the like, which is not specifically limited in the embodiment of the present disclosure.

It is to be noted that the above are merely preferred embodiments of the present disclosure and the technical principles used therein. It will be understood by those skilled in the art that the present disclosure is not limited to the specific embodiments described herein, and that the features of the various embodiments of the present disclosure may be coupled or combined in part or in whole with each other, and may be collaborated with each other and technically driven in various ways. Those skilled in the art can make various apparent modifications, adaptations, combinations and substitutions without departing from the scope of the present disclosure. Therefore, while the present disclosure has been described in detail through the above-mentioned embodiments, the present disclosure is not limited to the above-mentioned embodiments and may include more other equivalent embodiments without departing from the concept of the present disclosure. The scope of the present disclosure is determined by the scope of the appended claims.

What is claimed is:

1. An array substrate, comprising:
a substrate; and
a first thin film transistor and a second thin film transistor, wherein the first thin film transistor and the second thin film transistor are disposed on a side of the substrate; the first thin film transistor comprises a first active layer, a first A electrode and a first B electrode, wherein the first active layer comprises an oxide semiconductor active layer; and wherein the second thin film transistor comprises a second active layer, a second A electrode and a second B electrode, wherein the second active layer comprises a low temperature polysilicon active layer; and
wherein a film where the first active layer is located is disposed on a side of a film where the second active layer is located facing away from the substrate, and in a direction perpendicular to a plane where the substrate is located, a film where the first A electrode is located, a film where the first B electrode is located, a film where the second A electrode is located and a film where the second B electrode is located each are disposed between the film where the first active layer is located and the film where the second active layer is located.

2. The array substrate of claim 1, wherein the first A electrode and the second A electrode are arranged at a same layer and are electrically connected to each other; and
wherein in the direction perpendicular to the plane where the substrate is located, the first active layer has an overlapping portion with the first A electrode, wherein for the overlapping portion, a surface of the first active layer facing towards the substrate is in direct contact with a surface of the first A electrode facing away from the substrate.

3. The array substrate of claim 2, wherein
the second thin film transistor further comprises a second gate; wherein a film where the second gate is located is disposed between the film where the second active layer is located and a film where the second A electrode and the second B electrode are located;
the first B electrode and the second gate are arranged in a same layer and are electrically connected to each other; and
the first B electrode is electrically connected to the first active layer through a first via.

4. The array substrate of claim 2, wherein
the second thin film transistor further comprises a second gate; wherein a film where the second gate is located is disposed between the film where the second active layer is located and a film where the second A electrode and the second B electrode are located;
the first A electrode and the first B electrode are arranged at a same layer;
in the direction perpendicular to the plane where the substrate is located, the first active layer has an overlapping portion with the first B electrode, wherein for the overlapping portion, the surface of the first active layer facing towards the substrate is in direct contact with a surface of the first B electrode facing away from the substrate; and
the first B electrode is electrically connected to the second gate through a second via.

5. The array substrate of claim 1, wherein
the second thin film transistor further comprises a second gate; wherein a film where the second gate is located is disposed between the film where the second active layer is located and a film where the second A electrode and the second B electrode are located;
the first A electrode, the first B electrode and the second gate are arranged at a same layer, and the first B electrode is electrically connected to the second gate;
in the direction perpendicular to the plane where the substrate is located, the first active layer has an overlapping portion with the second A electrode;
the first A electrode is electrically connected to the second A electrode and the first active layer separately through a third via; and
the first B electrode is electrically connected to the first active layer through a fourth via.

6. The array substrate of claim 1, wherein
the first thin film transistor further comprises a first gate;
the array substrate further comprises a first gate insulating layer and a first passivation layer, wherein the first gate insulating layer is provided with a same shape as the first gate; and
the first active layer comprises a first A electrode area, a first B electrode area and a first channel area between the first A electrode area and the first B electrode area;
the first gate insulating layer is disposed on a side of the first active layer facing away from the substrate, and in the direction perpendicular to the plane where the substrate is located, the first gate insulating layer overlaps the first channel area;
the first gate is disposed on a side of the first gate insulating layer facing away from the substrate, and in the direction perpendicular to the plane where the substrate is located, the first gate overlaps the first gate insulating layer; and
the first passivation layer covers the first gate, a part of the first active layer, the second A electrode and the second B electrode.

7. The array substrate of claim 1, wherein
the first thin film transistor further comprises a first gate;
the array substrate further comprises a second passivation layer; and
the first active layer comprises a first A electrode area, a first B electrode area and a first channel area between the first A electrode area and the first B electrode area;
the second passivation layer covers the first active layer, the second A electrode and the second B electrode; and
the first gate is disposed on a side of the second passivation layer facing away from the substrate, and in the direction perpendicular to the plane where the substrate is located, the first gate has an overlapping portion with the first channel area.

8. The array substrate of claim 1, wherein
the array substrate further comprises a buffer layer, a second gate insulating layer and an interlayer insulating layer, and the second thin film transistor further comprises a second gate;
the buffer layer is disposed between the film where the second active layer is located and the substrate; and
the second active layer comprises a second A electrode area, a second B electrode area and a second channel area between the second A electrode area and the second B electrode area;
wherein the second gate insulating layer is disposed on a side of the second active layer facing away from the substrate;
the second gate is disposed on a side of the second gate insulating layer facing away from the substrate, and in the direction perpendicular to the plane where the substrate is located, the second gate has an overlapping portion with the second channel area;
the interlayer insulating layer is disposed on a side of the second gate facing away from the substrate; and
the second A electrode and the second B electrode are disposed on a side of the interlayer insulating layer facing away from the substrate, the second A electrode is electrically connected to the second A electrode area through a fifth via which penetrates through the interlayer insulating layer and the second gate insulating layer, and the second B electrode is electrically connected to the second B electrode area through a sixth via which penetrates through the interlayer insulating layer and the second gate insulating layer.

9. The array substrate of claim 1, wherein the array substrate further comprises an anode electrode, wherein the anode electrode is electrically connected to the second A electrode.

10. A display panel, comprising: an array substrate, an opposing substrate disposed facing to the array substrate and a light-emitting element between the array substrate and the opposing substrate;
wherein the array substrate, comprises:
a substrate; and
a first thin film transistor and a second thin film transistor, wherein the first thin film transistor and the second thin film transistor are disposed on a side of the substrate; the first thin film transistor comprises a first active layer, a first A electrode and a first B electrode, wherein the first active layer comprises an oxide semiconductor active layer; and wherein the second thin film transistor comprises a second active layer, a second A electrode and a second B electrode, wherein the second active layer comprises a low temperature polysilicon active layer; and
wherein a film where the first active layer is located is disposed on a side of a film where the second active layer is located facing away from the substrate, and in a direction perpendicular to a plane where the substrate is located, a film where the first A electrode is located, a film where the first B electrode is located, a film where the second A electrode is located and a film where the second B electrode is located each are disposed between the film where the first active layer is located and the film where the second active layer is located.

11. A display device, comprising a display panel;
wherein the display panel, comprises: an array substrate, an opposing substrate disposed facing to the array substrate and a light-emitting element between the array substrate and the opposing substrate;
wherein the array substrate, comprising: a substrate, and a first thin film transistor and a second thin film transistor, wherein the first thin film transistor and the second thin film transistor are disposed on a side of the substrate; the first thin film transistor comprises a first active layer, a first A electrode and a first B electrode, wherein the first active layer comprises an oxide semiconductor active layer; and wherein the second thin film transistor comprises a second active layer, a second A electrode and a second B electrode, wherein the second active layer comprises a low temperature polysilicon active layer; and
wherein a film where the first active layer is located is disposed on a side of a film where the second active layer is located facing away from the substrate, and in a direction perpendicular to a plane where the substrate is located, a film where the first A electrode is located, a film where the first B electrode is located, a film where the second A electrode is located and a film where the second B electrode is located each are disposed between the film where the first active layer is located and the film where the second active layer is located.
